(19) United States
(12) Patent Application Publication
(10) Pub. No.: US 2015/0076924 A1
(43) Pub. Date: Mar. 19, 2015

(54) SEMICONDUCTOR DEVICE

(71) Applicant: SK hynix Inc., Gyeonggi-do (KR)

(72) Inventors: Hyun-Seok KIM, Gyeonggi-do (KR); Sung-Woo HAN, Gyeonggi-do (KR); Ic-Su OH, Gyeonggi-do (KR); Jun-Ho LEE, Gyeonggi-do (KR); Boo-Ho JUNG, Gyeonggi-do (KR); Sun-Ki CHO, Gyeonggi-do (KR); Tae-Hoon KIM, Gyeonggi-do (KR); Ki-Chul HONG, Gyeonggi-do (KR)

(73) Assignee: SK hynix Inc., Gyeonggi-do (KR)

(21) Appl. No.: 14/107,826

(22) Filed: Dec. 16, 2013

(30) Foreign Application Priority Data
Sep. 13, 2013 (KR) 10-2013-0110216

(51) Int. Cl. H03K 17/687

(52) U.S. Cl. CPC H03K 17/687
USPC 307/115

(57) ABSTRACT

This technology provides a semiconductor device capable of controlling an equivalent series resistance (ESR) generated from decoupling capacitors. To this end, the semiconductor device may include a plurality of decoupling capacitors electrically coupled between a first wire and a second wire in parallel, and a plurality of switches coupled between common source/drain terminals of two adjacent decoupling capacitors of the plurality of decoupling capacitors and the second wire.

### CROSS-REFERENCE TO RELATED APPLICATIONS

The present application claims priority of Korean Patent Application No. 10-2013-0110216, filed on Sep. 13, 2013, which is incorporated herein by reference in its entirety.

### BACKGROUND

1. Field

Exemplary embodiments of the present invention relate to a semiconductor design technology, and more particularly, to a semiconductor device including decoupling capacitors.

2. Description of the Related Art

Recently, in designing semiconductor devices, a decoupling capacitor is used to remove high frequency noise of an on-chip. In particular, the decoupling capacitor serves to prevent a portion of the semiconductor device, which supplies a voltage to the semiconductor device, from being influenced by noise due to conditions of inside and outside the on-chip. The decoupling capacitor for reducing a parasitic component generates another parasitic component called an equivalent series resistance (ESR).

In general, a decoupling capacitor is implemented with a metal-oxide semiconductor (MOS) capacitor having a gate coupled to a first power source and a source and drain combined and coupled to a second power source. When a decoupling capacitor is formed of a MOS capacitor as described above, the ESR is determined by a gate length and width of the MOS capacitor. Accordingly, after a decoupling capacitor having a specific gate length and width is designed and fabricated, an ESR component becomes inevitably fixed and is difficult to be changed. It is however necessary to control the ESR component because the frequency of a product may be changed depending on the application of the product.

### SUMMARY

Various exemplary embodiments are directed to a semiconductor device in which an ESR of a decoupling capacitor may be controlled depending on a varying frequency environment.

In an exemplary embodiment, a semiconductor device may include a decoupling capacitor unit coupled between a first wire and a second wire, and an ESR control unit suitable for controlling an equivalent series resistance (ESR) of the decoupling capacitor unit.

In an exemplary embodiment, the decoupling capacitor unit may include a plurality of decoupling capacitors coupled between the first wire and the second wire in parallel.

In an exemplary embodiment, the decoupling capacitor unit may further include a common source/drain terminal in which the drain terminal of one decoupling capacitor and the source terminal of the other decoupling capacitor are coupled and shared.

In an exemplary embodiment, the ESR control unit may include means for electrically coupling or decoupling the common source/drain terminal to or from the second wire.

In an exemplary embodiment, the ESR control unit may include a plurality of switches coupled between the common source/drain terminal and the second wire and a switch control unit configured to output a plurality of control signals corresponding to the plurality of switches.

In another exemplary embodiment, a semiconductor device may include a plurality of decoupling capacitors coupled between a first wire and a second wire in parallel, and a plurality of switches coupled between common source/drain terminals of adjacent decoupling capacitors of the plurality of decoupling capacitors and the second wire.

In an embodiment, the semiconductor device may further include a switch control unit suitable for controlling the plurality of switches, and outputting a plurality of control signals corresponding to the plurality of switches.

In an embodiment, the plurality of decoupling capacitors and the plurality of switches may be grouped into a plurality of groups, and the switch control unit may output the control signal having the same pattern to each of the groups.

In an embodiment, the switch control unit may be implemented with a mode register set (MRS) for controlling a memory operation mode.

In an embodiment, the first wire may be a power source voltage line and the second wire may be a ground voltage line, or the first wire and the second wire may be wires that form a voltage generation circuit.

In still another exemplary embodiment, a semiconductor device may include a decoupling capacitor unit electrically coupled between a first wire and a second wire, and a control unit suitable for controlling an equivalent series resistance (ESR) component of the decoupling capacitor unit by electrically coupling or decoupling the decoupling capacitor unit to or from the second wire.

### BRIEF DESCRIPTION OF THE DRAWINGS

FIG. 1 is a block diagram illustrating a semiconductor device in accordance with an exemplary embodiment of the present invention.

FIG. 2 is a detailed circuit diagram illustrating the semiconductor device of FIG. 1.

FIGS. 3 and 4 are circuit diagrams illustrating the semiconductor device in which an ESR has been controlled.

FIG. 5 is a graph showing a change of an ESR depending on the number of turned-on switches of a switching unit.

FIG. 6 is a graph showing an on-chip impedance curve when the number of turned-on switches of the switching unit is decreased.

FIG. 7 is a graph showing variation in power noise of a semiconductor device in accordance with an exemplary embodiment of the present invention.

FIG. 8 is a circuit diagram showing a power generation circuit in accordance with an exemplary embodiment of the present invention.

### DETAILED DESCRIPTION

Various exemplary embodiments will be described below in more detail with reference to the accompanying drawings. The present invention may, however,be embodied in different forms and should not be construed as limited to the embodiments set forth herein. Rather, these embodiments are provided so that this disclosure will be thorough and complete, and will fully convey the scope of the present invention to those skilled in the art. The drawings are not necessarily to scale and in some instances, proportions may have been exaggerated in order to clearly illustrate features of the embodiments. Throughout the disclosure, reference numerals correspond directly to the like numbered parts in the various figures and embodiments of the present invention. It is also noted that in this specification, “connected/coupled” refers to one component not only directly coupling another component but also indirectly coupling another component through an intermediate component. In addition, a singular form may include a plural form as long as it is not specifically mentioned in a sentence.

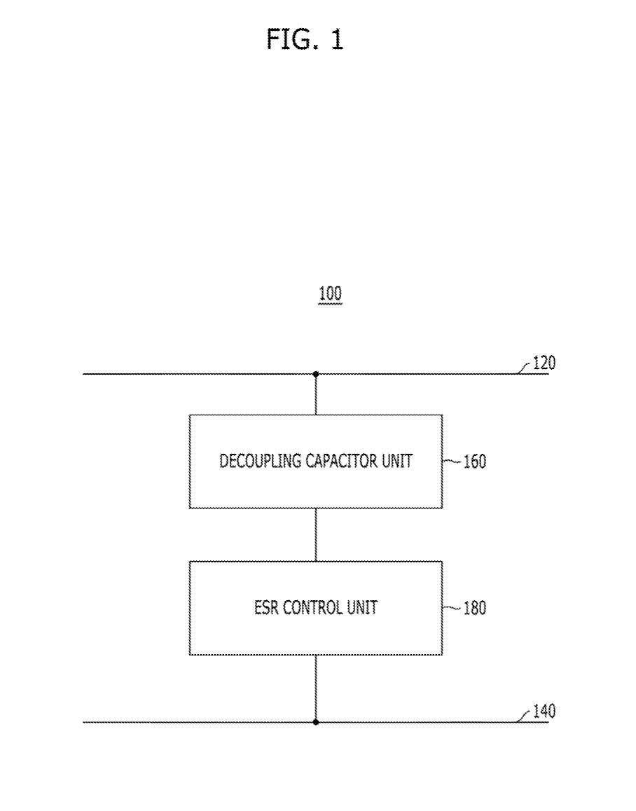

FIG. 1 is a block diagram illustrating a semiconductor device in accordance with an exemplary embodiment of the present invention.

Referring to FIG. 1, the semiconductor device 100 may include a first wire 120, a second wire 140, a decoupling capacitor unit 160 coupled between the first wire 120 and the second wire 140, and an ESR control unit 180 configured to control an equivalent series resistance (ESR) component of the decoupling capacitor unit 160.

A quality factor (Q-factor) that means quality, that is, a frequency selective characteristic, is represented as in Equation 1.

Q_{C}=X_{C}/R_{C}=1W_{O}*C*R_{C}, [Equation 1]

where W_{O} denotes a resonant frequency, C denotes capacitance, X_{C} denotes reactance, and R_{C} denotes serial resistance.

In Equation 1, the Q-factor is increased as the serial resistance R_{C} is decreased and is also increased as resistance between a power domain and a ground domain of an on-chip is decreased. As a resistance component becomes smaller, a high frequency characteristic may be improved, but an intermediate frequency characteristic is deteriorated because a Q-factor is increased. That is, in a power delivery network, performance may be deteriorated even if a Q-factor is increased. In such a case, power noise may be reduced if a Q-factor characteristic depending on an operating frequency of an application may be controlled by increasing or decreasing resistance between wires.

To this end, in FIG. 1, the ESR control unit 180 is provided to control the ESR component of the decoupling capacitor unit 160 coupled between the first wire 120 and the second wire 140.

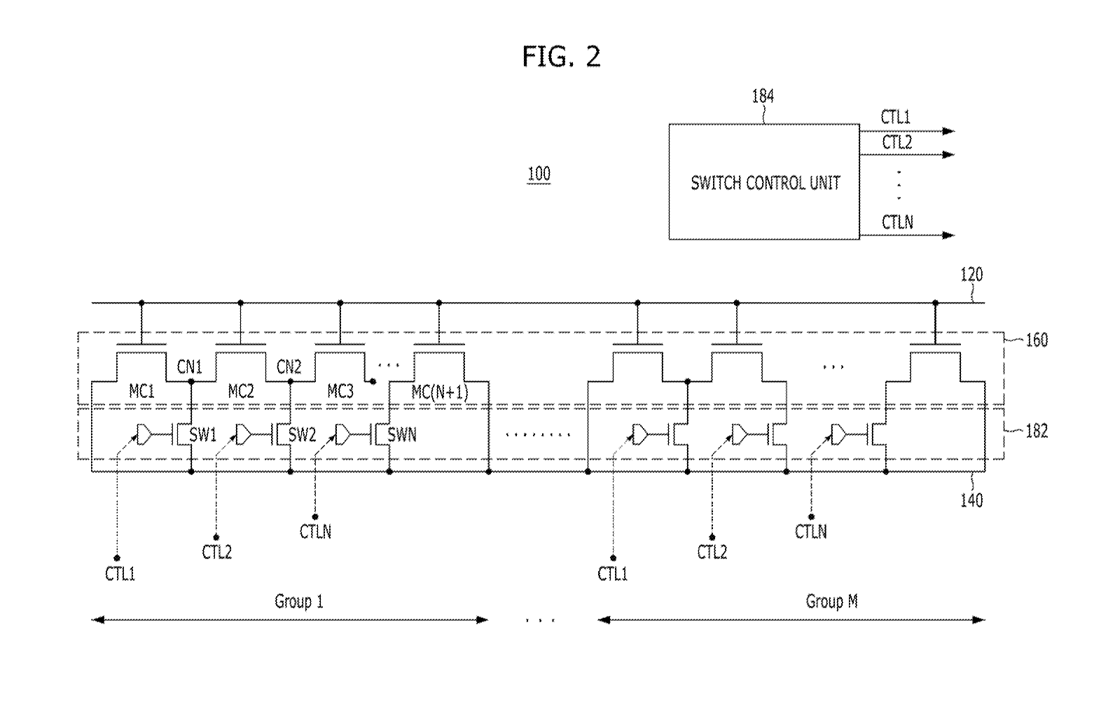

FIG. 2 is a detailed circuit diagram illustrating the semiconductor device 100 shown in FIG. 1.

Referring to FIG. 2, the semiconductor device 100 in accordance with the exemplary embodiment may include the first wire 120, the second wire 140, the decoupling capacitor unit 160, switching unit 182, and a switch control unit 184.

The decoupling capacitor unit 160 may include a plurality of decoupling capacitors MC coupled between the first wire 120 and the second wire 140 in parallel. Furthermore, in adjacent decoupling capacitors, e.g., MC1 and MC2, a drain terminal of one decoupling capacitor MC1 and a source terminal of the other decoupling capacitor MC2 are coupled in common. That is, the decoupling capacitor unit 160 may further include a plurality of common source/drain terminals CN, each coupled between two adjacent decoupling capacitors.

In the present embodiment, the ESR component of the decoupling capacitor unit 160 is controlled by electrically coupling or decoupling the common source/drain terminals CN to or from the second wire 140.

The switching unit 182 and the switch control unit 184 control the ESR component of the decoupling capacitor unit 160. That is, the switching unit 182 and the switch control unit 184 may correspond to the ESR control unit 180 of FIG. 1.

The switching unit 182 may include a plurality of switches SW coupled between the common source/drain terminals CN and the second wire 140, and the switch control unit 184 configured to output a plurality of control signals CTL1, CTL2, . . . , CTLN corresponding to the plurality of switches SW. For example, N control signals CTL1, CTL2, . . . , CTLN may correspond to N switches SW1, SW2, . . . , SWN, one to one, and the first control signal CTL1 may control the turn-on and turn-off of the first switch SW1.

The decoupling capacitors MC and the plurality of switches SW may be grouped into a plurality of groups, each group including (N+1) decoupling capacitors MC1 MC2, . . . , MC(N+1) of the decoupling capacitor unit 160, and N switches SW1, SW2, . . . , SWN of the switching unit 182. The present embodiment shows that the decoupling capacitors MC and the plurality of switches SW are grouped into M groups. Furthermore, the switch control unit 184 may output the control signals CTL1, CTL2, . . . , CTLN to the respective groups.

In the present embodiment, the first wire 120 and the second wire 140 may be a line for a power source voltage Vdd or a line for a ground voltage Vss, respectively. The first wire 120 may be a power source voltage line, and the second wire 140 may be a ground voltage line.

Each of the switches SW may be implemented with a semiconductor switching element such as a MOS transistor or a pass gate.

The control signals CLT1 to CLTN may be generated using a method for generating a test mode signal. For example, logic values of the control signals CLT1 to CLTN may be changed depending on the setting of a mode register set (MRS).

In the present embodiment, the overall capacitance and resistance may be controlled by turning on or off the switches coupled between two adjacent decoupling capacitors.

That is, when the number of switches that are turned on is increased, capacitance of the decoupling capacitors is increased, but resistance of the decoupling capacitors is decreased. In contrast, when the number of switches that are turned off is increased, capacitance of the decoupling capacitors is deceased, but resistance of the decoupling capacitors is increased.

The switch control unit 184 may be designed outside the semiconductor device not inside the semiconductor device, and may be designed to receive the control signals CLT1 to CLTN from the outside through a specific pin, e.g., an extra address pin of the semiconductor chip.

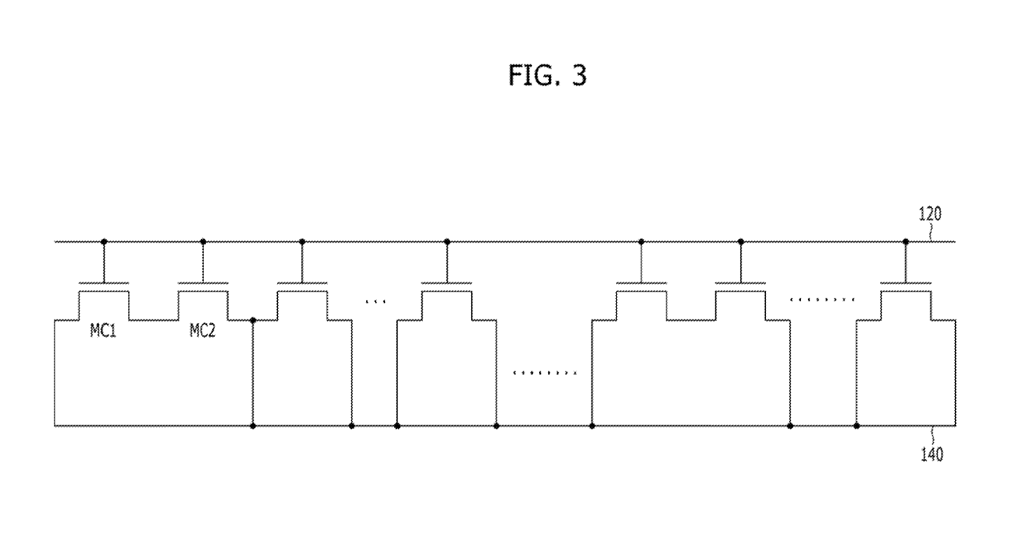

FIGS. 3 and 4 are equivalent circuit diagrams of the semiconductor device whose ESR has been controlled.

FIG. 3 shows that the first common source/drain terminal CN1 between the decoupling capacitors MC1 and MC2 in each group is not electrically coupled to the second wire 140 because the first switch SW1 is turned off in response to the first control signal CTL1 in FIG. 2. FIG. 4 shows that the first and second common source/drain terminals CN1 and CN2 between the decoupling capacitors MC1, MC2, and MC3 in each group are not electrically coupled to the second wire 140 because the first and second switches SW1 and SW2 are turned of in response to the first and second control signals CTL1 and CTL2 in FIG. 2.

That is, FIGS. 3 and 4 show that the X common source/drain terminals CN between (X+1) decoupling capacitors is not electrically coupled to the second wire 140 by turning off X switches in response to the X control signals CTL. For reference, X is a positive integer less than N, X becomes 1 in FIG. 3, and X becomes 2 in FIG. 4.

When one switch SW is turned off in response to one control signal CTL, the source and drain of two adjacent decoupling MOS capacitors are coupled so that two adjacent decoupling MOS capacitors are coupled in series as shown in FIG. 3. When two switches SW are turned off in response to two control signals CTL, the sources and drains of three adjacent decoupling capacitors are coupled so that three adjacent decoupling MOS capacitors are coupled in series as shown in FIG. 4. Accordingly, when X switches SW are turned off in response to X control signals CTL, the common source/drain terminals of (X+1) adjacent decoupling MOS capacitors are coupled so that (X+1) adjacent decoupling MOS capacitors are coupled in series.

Accordingly, the gate length of the decoupling capacitor may be controlled in response to the control signal. As a result, the ESR component of the decoupling capacitor unit 160 may be controlled by the switching unit 182 and the switch control unit 184 of the ESR control unit 180.

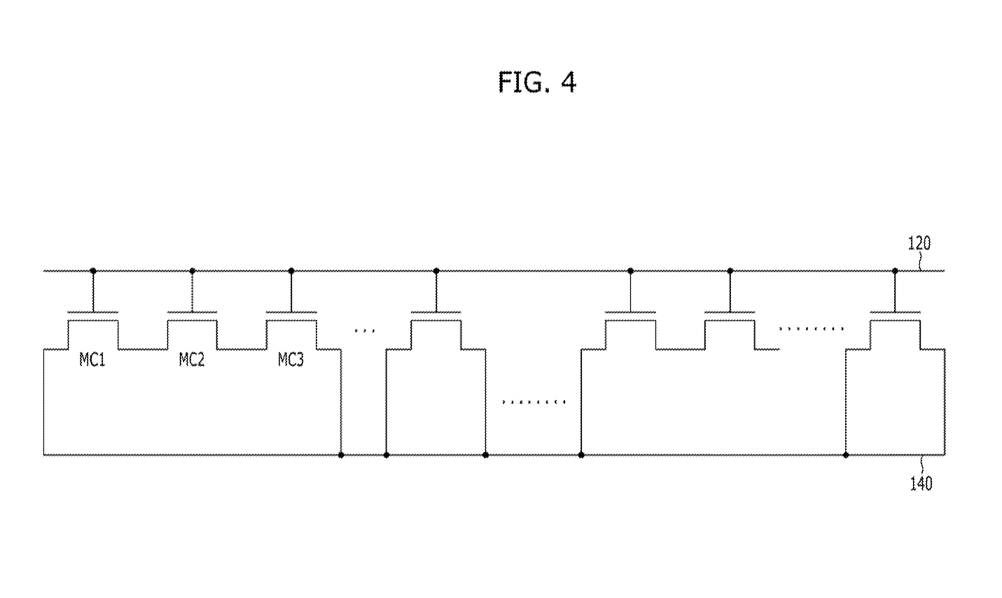

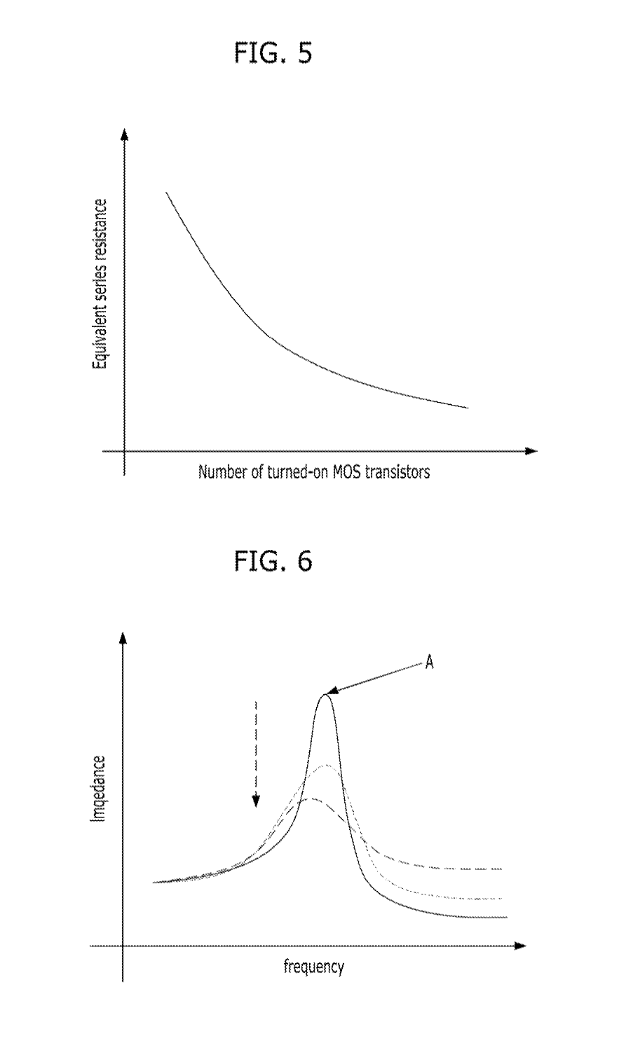

FIG. 5 is a graph showing a change of an ESR depending on the number of turned-on switches of the switching unit 182, and FIG. 6 is a graph showing an on-chip impedance curve when the number of turned-on switches SW is decreased.

Referring to FIG. 5, as the number of switches SW that are turned on is decreased, the ESR component of the decoupling capacitors may be increased as the number of switches SW that are turned on is increased, the ESR component of the decoupling capacitors may be decreased.

Referring to FIG. 6, as the number of turned-on switches SW is decreased, a resonant point A is lowered and a Q-factor is also decreased because the ESR component of the decoupling capacitors is increased. Accordingly, a sharpness of the on-chip impedance curve may be smooth. However, an electric current flow may improve because an intermediate frequency has a better characteristic. For reference, a resonant frequency is a frequency from which a phase difference between the resonant frequency and interference signals that may serve as interference has been removed.

That is, the ESR component of the decoupling capacitor MC may be controlled by changing the gate size of the decoupling capacitor MC using a method described in the present embodiment. Accordingly, a Q-factor suitable for the operating frequency of an application may be obtained because the ESR component of the decoupling capacitor MC may be controlled by changing the gate size of the decoupling capacitor MC according to the operating frequency of the application.

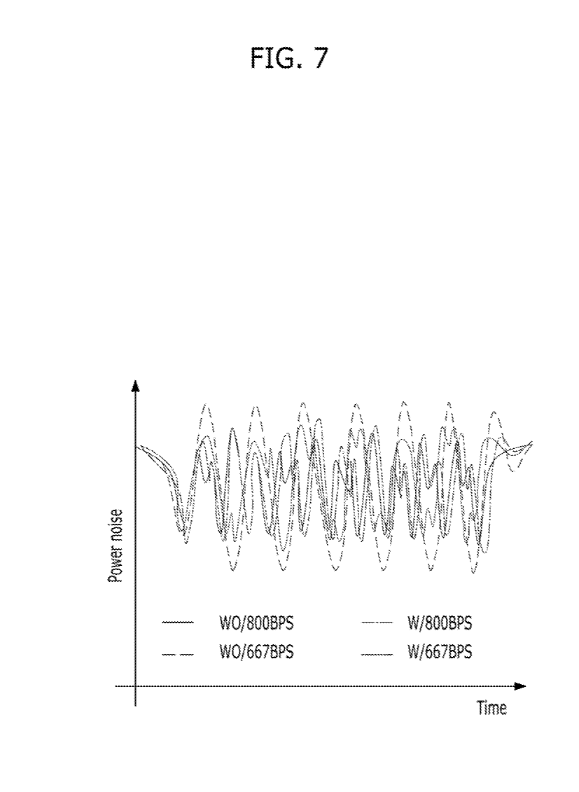

FIG. 7 is a graph showing variation in power noise of a semiconductor device in accordance with an exemplary embodiment of the present invention.

Referring to FIG. 7, read/write operations in 800 bit per second (BPS) and 667 BPS, respectively, are illustrated. That is, two different operating speeds of a dynamic random access memory (DRAM) are illustrated.

In FIG. 7, ‘WO/ (without)’ indicates a case of the semiconductor device excluding the decoupling circuits in accordance with the embodiment of the present invention, and ‘W/ (with)’ indicates a case of the semiconductor device including the decoupling circuits in accordance with the embodiment of the present invention. From FIG. 7, it may be seen that variation in power noise of ‘WO/800 BPS’ is greater than that in ‘W/800 BPS’ and variation in power noise of ‘WO/667 BPS’ is greater than that in ‘W/667 BPS’. Accordingly, the supply of power is more stable when the semiconductor device includes the decoupling circuits than when the semiconductor device does not include the decoupling circuits.

Additionally, since a value of voltage may be represented by the product of an impedance value and consumption power, the voltage is proportional to the impedance value assuming that a consumption current is fixed. The supply of power may become stable because an impedance value in resonance is decreased as ESR, that is, a parasitic resistance value, is increased.

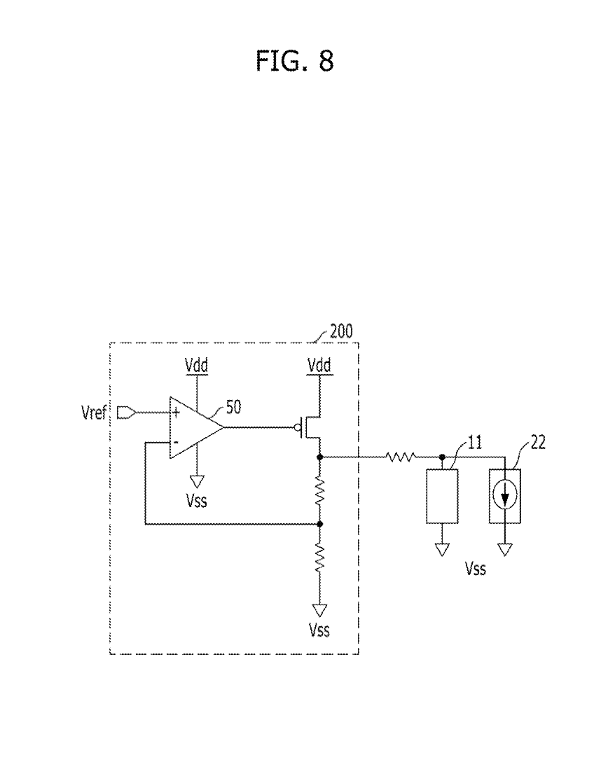

FIG. 8 is a circuit diagram showing a power generation circuit in accordance with an exemplary embodiment of the present invention. FIG. 8 illustrates the power generation circuit to which a decoupling circuit having controllable ESR in accordance with an exemplary embodiment of the present invention is applied.

Referring to FIG. 8, the power generation circuit in accordance with the embodiment may include a decoupling circuit 11 having a controllable ESR component, an internal power generation circuit 200, and an internal circuit block 22.

The internal circuit block 22 is driven by a power source voltage Vdd and a ground voltage Vss. Furthermore, the internal power generation circuit 200 is described by taking a low drop out (LDO) circuit (also called a voltage down converter), belonging to internal power generation circuits for generating the power source voltage Vdd used in a semiconductor device, as an example. The power generation circuit 200 in accordance with the embodiment is advantageous from a phase margin viewpoint, which is important in the circuit design in the LDO circuit, because it includes the decoupling circuit 11. The present invention may also be applied to a circuit including another amplifier for driving a large transistor other than the LDO circuit.

Furthermore, the embodiment of the present invention may be applied to a differential amplification comparator 50 included in the internal power generation circuit 200.

Most of semiconductor devices include many circuits for generating internal voltages based on external voltages. For example, a semiconductor memory device may includes many circuits for generating internal voltages such as a core voltage VCORE, a back-bias voltage VBB, and a high voltage VPP, based on a power source voltage Vdd, that is, an external voltage. Internal circuits are driven by the internal voltages generated from the circuits, and the present invention may also be applied to such voltage generation circuits.

In accordance with this technology, in the improved semiconductor device of the aforementioned embodiment, an ESR of decoupling capacitors may be controlled depending on a varying frequency environment.

Although various embodiments have been described for illustrative purposes, it will be apparent to those skilled in the art that various changes and modifications may be made without departing from the spirit and scope of the invention as defined in the following claims.

What is claimed is:

1. A semiconductor device comprising:
a plurality of decoupling capacitors electrically coupled between a first wire and a second wire in parallel; and
a plurality of switches coupled between common source/drain terminals of two adjacent decoupling capacitors of the plurality of decoupling capacitors and the second wire.

2. The semiconductor device of claim 1, further comprising a switch control unit suitable for controlling the plurality of switches.

3. The semiconductor device of claim 2, wherein the switch control unit selectively turns on or off the plurality of switches in response to a plurality of control signals.

4. The semiconductor device of claim 2, wherein the plurality of decoupling capacitors are grouped into a plurality of groups.

5. The semiconductor device of claim 4, wherein the switch control unit turns on or off the plurality of switches in response to a plurality of control signals applied to the respective groups.

6. The semiconductor device of claim 2, wherein the switch control unit comprises a mode register set (MRS)

7. The semiconductor device of claim 1, wherein each of the plurality of switches comprises at least one transistor.

8. The semiconductor device of claim 1, wherein
the first wire is a power source voltage line, and
the second wire is a ground voltage line.

9. The semiconductor device of claim 1, wherein, when N switches are turned off, gates of (N+1) decoupling capacitors having common source/drain terminals coupled to the turned-off switches are coupled, N being a positive integer.

10. The semiconductor device of claim 1, wherein, as the number of the switches that are turned on increases, capacitance of the decoupling capacitors is increased and resistance of the decoupling capacitors is decreased.

11. The semiconductor device of claim 1, wherein, as the number of the switches that are turned off increases, capacitance of the decoupling capacitors is decreased and resistance of the decoupling capacitors is increased.

12. A semiconductor device comprising:
a decoupling capacitor unit electrically coupled between a first wire and a second wire; and
a control unit suitable for controlling an equivalent series resistance (ESR) component of the decoupling capacitor unit by electrically coupling or decoupling the decoupling capacitor unit to or from the second wire.

13. The semiconductor device of claim 12, wherein the control unit comprises:
a switch control unit suitable for generating a plurality of control signals; and
a switching unit electrically coupling or decoupling the decoupling capacitor unit to or from the second wire in response to the control signals.

14. The semiconductor device of claim 13, wherein the decoupling capacitor unit includes a plurality of decoupling capacitors coupled between the first wire and the second wire in parallel, and the switching unit includes a plurality of switches, each switch coupled between a common terminal of two adjacent decoupling capacitors and the second wire.

15. The semiconductor device of claim 14, wherein each of the decoupling capacitors includes metal-oxide semiconductor (MOS) capacitor having a gate coupled to the first wire and a source and drain coupled to the second wire.

16. The semiconductor device of claim 14, wherein each of the switches comprises at least one transistor having a gate receiving the respective control signal and a source and drain coupled between the common terminal and the second wire.

17. The semiconductor device of claim 14, wherein the decoupling capacitors and the switches are grouped into a plurality of groups, each group including (N+1) decoupling capacitors and N switches, N being a positive integer.

18. The semiconductor device of claim 17, wherein the switch control unit outputs the control signals to the respective groups.

19. The semiconductor device of claim 13, wherein the switch control unit comprises a mode register set (MRS).
